(19) United States
(12) Patent Application Publication
(10) Pub. No.: US 2024/0128159 A1
(43) Pub. Date: Apr. 18, 2024

(54) INTEGRATED CIRCUIT INCLUDING STANDARD CELL WITH A METAL LAYER HAVING A PATTERN AND METHOD OF MANUFACTURING THE SAME

(71) Applicant: SAMSUNG ELECTRONICS CO., LTD., Suwon-si (KR)

(72) Inventors: Minjae JEONG, Suwon-si (KR); Jaehee CHO, Suwon-si (KR); Geonwoo NAM, Suwon-si (KR); Jungho DO, Suwon-si (KR); Jisu YU, Suwon-si (KR); Hyeongyu YOU, Suwon-si (KR); Seungyoung LEE, Suwon-si (KR)

(21) Appl. No.: 18/367,549

(22) Filed: Sep. 13, 2023

(30) Foreign Application Priority Data
Oct. 12, 2022 (KR) 10-2022-0130923

(51) Int. Cl. H01L 23/48; H01L 21/8238; H01L 27/092; H01L 29/06; H01L 29/423; H01L 29/66; H01L 29/775; H01L 29/786

(52) U.S. Cl. CPC H01L 23/481; H01L 21/823807; H01L 21/823871; H01L 27/092; H01L 29/0673; H01L 29/42392; H01L 29/66439; H01L 29/775; H01L 29/78696

(57) ABSTRACT

An integrated circuit including a standard cell including: a metal layer including a pattern extending in a first horizontal direction and a plurality of tracks spaced apart from one another in a second horizontal direction, wherein the plurality of tracks include a plurality of cell tracks and one power distribution network (PDN) track, wherein cell patterns are formed on the plurality of cell tracks, and a PDN pattern or a routing pattern is formed on the one power distribution network (PDN) track, wherein a first pattern is spaced apart from a cell boundary of the standard cell by a first length and is formed on a first cell track among the plurality of cell tracks, and wherein a second pattern is spaced apart from a cell boundary of the standard cell by a second length and is formed on a second cell track among the plurality of cell tracks.

### CROSS-REFERENCE TO RELATED APPLICATION

This application claims priority under 35 U.S.C. § 119 to Korean Patent Application No. 10-2022-0130923, filed on Oct. 12, 2022, in the Korean Intellectual Property Office, the disclosure of which is incorporated by reference herein in its entirety.

### TECHNICAL FIELD

The present inventive concept relates to an integrated circuit and a method of manufacturing the same, and more particularly, to an integrated circuit including a standard cell with a metal layer having a pattern and a method of manufacturing the same.

### DISCUSSION OF THE RELATED ART

The integrated circuit may be designed based on standard cells. For example, a layout of the integrated circuit may be generated by placing standard cells according to data defining the integrated circuit and routing the placed standard cells. As semiconductor manufacturing processes become finer, a size of each of patterns in the standard cell may be reduced, and a size of the standard cell may also be reduced. As the size of the standard cell is reduced, the density of cell patterns in the standard cell increases, and the density of lines for interconnecting semiconductor devices to each other also increases.

### SUMMARY

According to an embodiment of the present inventive concept, an integrated circuit including a standard cell having a cell height in a first horizontal direction, wherein the standard cell includes: a metal layer including a pattern extending in the first horizontal direction and a plurality of tracks spaced apart from one another in a second horizontal direction; and at least one via connecting the metal layer to a lower pattern of the metal layer, wherein the plurality of tracks include a plurality of cell tracks and at least one power distribution network (PDN) track, wherein cell patterns are formed on the plurality of cell tracks, and a PDN pattern or a routing pattern is formed on the at least one power distribution network (PDN) track, wherein a first pattern is spaced apart from a cell boundary of the standard cell by a first length and is formed on a first cell track among the plurality of cell tracks, and wherein a second pattern is spaced apart from a cell boundary of the standard cell by a second length that is different from the first length and is formed on a second cell track among the plurality of cell tracks.

According to an embodiment of the present inventive concept, an integrated circuit including a standard cell defined by a cell boundary, wherein the standard cell includes: a first metal layer and a second metal layer that are sequentially stacked on a substrate, and in each of the first metal layer and the second metal layer, a plurality of patterns are formed; and at least one via electrically connecting a pattern of the first metal layer to a pattern of the second metal layer, wherein, on the second metal layer, a pattern extending in a first horizontal direction is formed and a plurality of tracks spaced apart from one another in a second horizontal direction are defined, wherein the plurality of tracks include a plurality of cell tracks and at least one power distribution network (PDN) track, wherein cell patterns are formed on the plurality of cell tracks, and a PDN pattern or a routing pattern is formed on the at least one power distribution network (PDN) track, wherein a first pattern is spaced apart from a cell boundary of the standard cell by a first length and is formed on a first cell track among the plurality of cell tracks, and wherein a second pattern is spaced apart from a cell boundary of the standard cell by a second length that is different from the first length and is formed on a second cell track among the plurality of cell tracks.

According to an embodiment of the present inventive concept, a method of manufacturing an integrated circuit, the method includes: forming a first standard cell including at least one of a staggered pattern and a long short pattern that are formed on a metal layer; and placing a second standard cell, which includes at least one of a staggered pattern and a long short pattern that are formed on the metal layer, adjacent to the first standard cell in a first horizontal direction considering tip-to-tip space requirement, wherein, on the metal layer, a pattern extending in the first horizontal direction is formed and a plurality of tracks spaced apart from one another in a second horizontal direction are provided, wherein the staggered pattern includes a first pattern and a second pattern, wherein the first pattern is formed on a first track among the plurality of tracks and is spaced apart from a cell boundary by a first length, and the second pattern is formed on a second track among the plurality of tracks and is spaced apart from a cell boundary by a second length that is different from the first length, wherein the long short pattern includes a third pattern and a fourth pattern, wherein the third pattern is formed on the first track among the plurality of tracks and is spaced apart from a cell boundary by a third length, and the fourth pattern is formed on the second track among the plurality of tracks and is spaced apart from a cell boundary by a fourth length that is different from the third length, wherein the first pattern of the staggered pattern and the second pattern of the staggered pattern have a same length as each other in the first horizontal direction, and wherein a length of the third pattern of the long short pattern is different from a length of the fourth pattern of the long short pattern in the first horizontal direction.

### BRIEF DESCRIPTION OF THE DRAWINGS

The above and other aspects of the present inventive concept will become more apparent by describing in detail embodiments thereof, with reference to the accompanying drawings, in which:

FIG. 1 is a layout diagram illustrating an integrated circuit according to an embodiment of the present inventive concept;

FIGS. 2A and 2B are cross-sectional views taken along the line A-A′ of FIG. 1;

FIG. 3 is a layout diagram illustrating a standard cell placed in an integrated circuit according to an embodiment of the present inventive concept;

FIG. 4 is a layout diagram illustrating a standard cell placed in an integrated circuit according to an embodiment of the present inventive concept;

FIG. 5 is a layout diagram illustrating a standard cell placed in an integrated circuit according to an embodiment of the present inventive concept;

FIG. 6 is a flowchart illustrating a method of manufacturing an integrated circuit, according to an embodiment of the present inventive concept;

FIG. 7 is a flowchart illustrating a method of manufacturing an integrated circuit, according to an embodiment of the present inventive concept;

FIGS. 8A, 8B, 8C, and 8D are layout diagrams illustrating standard cells placed in an integrated circuit according to an embodiment of the present inventive concept;

FIGS. 9, 10 and 11 are layout diagrams of integrated circuits according to an embodiment of the present inventive concept; and

FIG. 12 is a block diagram illustrating a computing system for designing an integrated circuit according to an embodiment of the present inventive concept.

### DETAILED DESCRIPTION OF THE EMBODIMENTS

Hereinafter, embodiments of the present inventive concept will be described in detail with reference to the accompanying drawings.

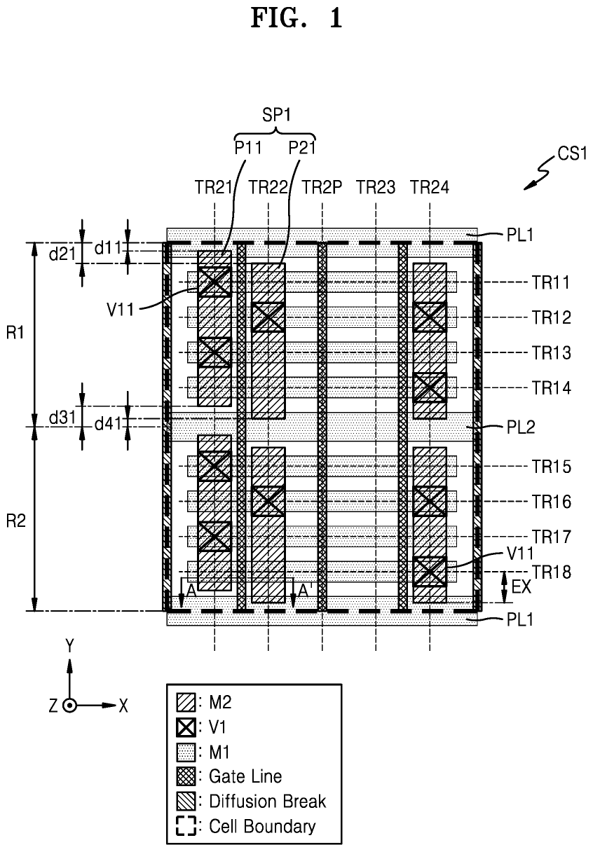

FIG. 1 is a layout diagram illustrating a standard cell placed in an integrated circuit according to an embodiment of the present inventive concept.

FIG. 1 is a plan view illustrating a standard cell CS1 constituting one chip or one functional block in a plane extending along an X axis and a Y axis. In the current specification, a Y-axis direction and an X-axis direction may be referred to as a first horizontal direction and a second horizontal direction, respectively, and a Z-axis direction may be referred to as a vertical direction. The plane extending along the X axis and the Y axis may be referred to as a horizontal plane. The component arranged in the Z-axis direction relative to other components may be referred to as being above the other component, and a component arranged in a reverse direction of the Z-axis direction relative to other components may be referred to as being below the other components.

The integrated circuit may include a plurality of standard cells. A standard cell, as a unit of a layout included in an integrated circuit, may be designed to perform a predefined function or may be referred to as a cell. The integrated circuit may include a plurality of various standard cells. The standard cells may be placed and aligned with one another in a plurality of rows, and a cell height may be in the Y direction.

The plurality of standard cells including the standard cell CS1 of FIG. 1 are repeatedly used for designing the integrated circuit. The standard cells may be pre-designed according to manufacturing technology and stored in a standard cell library, and the integrated circuit may be designed by placing and interconnecting the standard cells stored in the standard cell library according to design rules.

The standard cells may include logic cells. For example, the logic cells may implement circuits that constitute various basic circuits frequently used in digital circuit design of electronic devices such as a central processing unit (CPU), a graphics processing unit (GPU), and a system-on-chip (SoC), such as an inverter, an AND gate, a NAND gate, an OR gate, an XOR gate, and a NOR gate. In addition, for example, the logic cells may implement other circuits frequently used in circuit blocks, such as a flip-flop and a latch.

The standard cells may include filler cells. A filler cell is placed adjacent to a functional cell to provide routing of signals input to or output from the functional cell. In addition, the filler cell may fill a space left after functional cells are placed.

Referring to FIG. 1, a plurality of metal layers sequentially stacked in a vertical direction may be formed in the standard cell CS1. For example, a second metal layer M2 may be formed on a first metal layer M1. In an embodiment of the present inventive concept, the first metal layer M1 may include patterns extending in the X-axis direction, and the second metal layer M2 may include patterns extending in the Y-axis direction. Unlike in FIG. 1, another metal layer may be further formed on the second metal layer M2.

The patterns formed on the first and second metal layers M1 and M2 may include a metal, conductive metal nitride, metal silicide, or a combination thereof. In the drawings of the current specification, some layers may be illustrated for convenience of illustration, and a via may be displayed, but the via may be positioned under a pattern of a metal layer to represent a connection between the pattern of the metal layer and a lower pattern.

The standard cell CS1 may receive supply voltages from first power lines PL1 and a second power line PL2. The first power lines PL1 and the second power line PL2 may be placed at a boundary of each of a plurality of rows of the integrated circuit. The first power lines PL1 may provide a first supply voltage to each of the standard cells, and the second power line PL2 may provide a second supply voltage to each of the standard cells. Each of the first supply voltage and the second supply voltage may include a power voltage or a ground voltage.

The first power lines PL1 and the second power line PL2 may include conductive patterns extending in the X-axis direction and may be alternately placed in the Y-axis direction. Although it is illustrated in FIG. 1 that the first power lines PL1 and the second power line PL2 are formed as the patterns of the first metal layer M1, the integrated circuit according to the present inventive concept is not limited thereto, and the first power lines PL1 and the second power line PL2 may be formed as patterns of an upper metal layer of the first metal layer M1 or may be formed in isolation trenches formed in a substrate.

The standard cell CS1 may be defined by a cell boundary. For example, the standard cell CS1 may include a logic cell. A height of the standard cell CS1 may be in the Y-axis direction based on the cell boundary.

The first power lines PL1, the second power line PL2, and diffusion breaks may be formed on the cell boundary. The diffusion breaks may electrically isolate the standard cell CS1 from active regions of other standard cells. Although single diffusion breaks are illustrated in FIG. 1, double diffusion breaks may be formed on the cell boundary. The diffusion breaks may include a silicon-containing insulating layer such as a silicon oxide layer, a silicon nitride layer, a silicon oxynitride layer, a silicon carbonitride layer, or a combination thereof. For example, the diffusion breaks may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), or tonen silazene (TOSZ).

A plurality of tracks on which the patterns are placed may be defined in the first metal layer M1. The first metal layer M1 may be the lowermost metal layer among the plurality of metal layers. The plurality of tracks of the first metal layer M1 may extend in the X-axis direction and may be spaced apart from one another in the Y-axis direction. For example, first to eighth tracks TR11 to TR18 may be formed in the standard cell CS1. However, unlike in FIG. 1, the number of tracks of the first metal layer M1 passing through the cell boundary of the standard cell CS1 may vary.

In addition, a plurality of tracks on which the patterns are placed may be defined in the second metal layer M2. For example, the second metal layer M2, which is placed on the first metal layer M1, may be the second lowermost metal layer among the plurality of metal layers. The plurality of tracks of the second metal layer M2 may extend in the Y-axis direction and may be spaced apart from one another in the X-axis direction.

The plurality of tracks of the second metal layer M2 may include cell tracks (for example, TR21 to TR24) on which cell patterns are formed and at least one power distribution network (PDN) track TR2P on which a PDN pattern or a routing pattern is formed. For example, the first to fourth cell tracks TR21 to TR24 and the PDN track TR2P may be formed in the standard cell CS1. Cell patterns might not be formed on some (for example, the third cell track TR23) of the first to fourth cell tracks TR21 to TR24. Cell patterns may be repeatedly formed on the first to fourth cell tracks TR21 to TR24 based on the PDN track TR2P. For example, the second cell track TR22 and the fourth cell track TR24 may include cell patterns formed in the same manner.

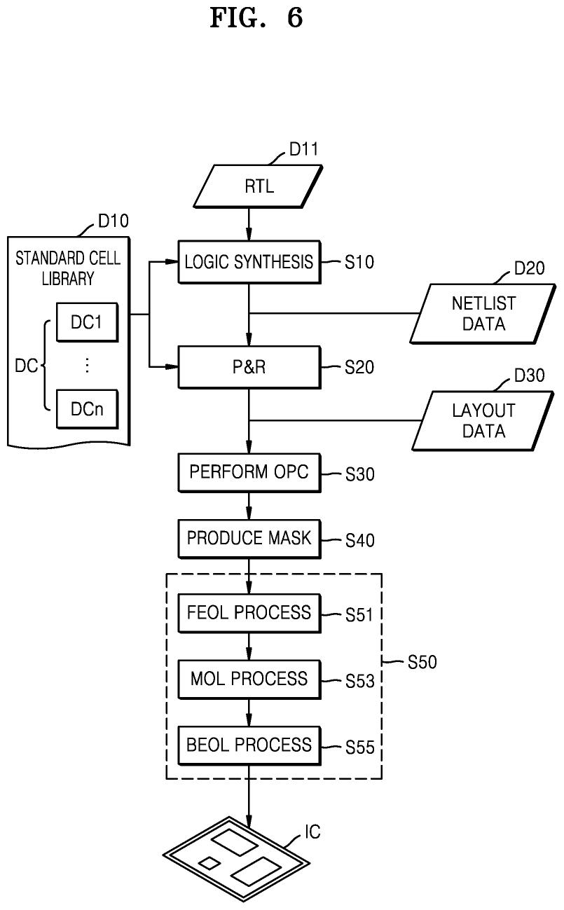

A cell pattern is not formed on the at least one PDN track TR2P, and the routing pattern or the PDN pattern may be formed on the at least one PDN track TR2P in a placement and routing process (for example, S20 of FIG. 6) after the standard cell CS1 is placed. The routing pattern may be electrically connected to an input/output pin of the standard cell CS1, and may provide an electrical connection for receiving/transmitting a signal input/output to/from the standard cell CS1 from/to another standard cell. The PDN pattern constituting a PDN may form a power mesh providing a supply voltage to the first power lines PL1 or the second power line PL2. However, unlike in FIG. 1, the number and configuration of tracks of the second metal layer M2 passing through the cell boundary of the standard cell CS1 may vary.

The standard cell CS1 may include a plurality of gate lines extending in the Y-axis direction and spaced apart from one another in the X-axis direction. In an embodiment of the present inventive concept, the first to fourth cell tracks TR21 to TR24 of the second metal layer M2 are not aligned with the plurality of gate lines, and may be spaced apart from the plurality of gate lines by a predetermined distance (a predetermined offset). For example, the first cell track TR21 may be spaced apart from the closest first gate line in a reverse direction of the X-axis direction by a certain distance, and the second cell track TR22 may be spaced apart from the closest first gate line in the X-axis direction by a certain distance. For example, the first cell track TR21 and the second cell track TR22 may be placed with the first gate line therebetween.

In an embodiment of the present inventive concept, the PDN track TR2P of the second metal layer M2 may be aligned with a specific gate line. However, the standard cell CS1 according to an embodiment of the present inventive concept is not limited to what is illustrated in FIG. 1, and the PDN track TR2P may be spaced apart from the plurality of gate lines in the X-axis direction.

The standard cell CS1 may include the patterns of the first metal layer M1 and the second metal layer M2. For example, the standard cell CS1 may include at least one staggered pattern SP1 formed on the second metal layer M2. A staggered pattern SP1 placed in a first row R1 may include, for example, a first cell pattern P11 and a second cell pattern P21. The first cell pattern P11 is formed on the first cell track TR21, and the second cell pattern P21 is formed on the second cell track TR22. The first cell pattern P11 and the second cell pattern P21 may be adjacent to each other in the X-axis direction. The first cell pattern P11 may be spaced apart from the cell boundary by a first length d11, and the second cell pattern P21 may be spaced apart from the cell boundary by a second length d21. For example, the first cell pattern P11 may be spaced apart from the first power line PL1 by the first length d11, and the second cell pattern P21 may be apart from the first power line PL1 by the second length d21. In addition, the first cell pattern P11 may be spaced apart from the second power line PL2 by a third length d31, and the second cell pattern P21 may be spaced apart from the second power line PL2 by a fourth length d41. At this time, the first length d11 may be less than the second length d21, and the third length d31 may be greater than the fourth length d41. In an embodiment of the present inventive concept, the first cell pattern P11 formed on the first cell track TR21 and the second cell pattern P21 formed on the second cell track TR22 may have the same length as each other.

The standard cell CS1 may further include a staggered pattern SP1 placed in a second row R2 and formed on the second metal layer M2. The patterns of the second metal layer M2 may be spaced apart from one another at designated intervals. An interval between patterns placed adjacent to each other on the same track of the second metal layer M2 may be defined as a tip-to-tip space, and the patterns of the second metal layer M2 may be placed so that the tip-to-tip space has a designated value. Because the staggered pattern SP1 is included in the first row R1 and the second row R2, the tip-to-tip space requirement in the second metal layer M2 may be satisfied.

The standard cell CS1 may include a plurality of first vias V1 electrically connected between the patterns of the first metal layer M1 and the patterns of the second metal layer M2. For example, second vias electrically connected to a third metal layer may be formed on the second metal layer M2.

In an embodiment of the present inventive concept, the plurality of first vias V1 included in the standard cell CS1 may include vias V11 connected to patterns that are formed on tracks closest to the cell boundary among the plurality of tracks TR11 to TR18 of the first metal layer M1, or tracks closest to the first power lines PL1 or the second power line PL2. The vias V11 may be connected to patterns of which ends, that is, tips, are closer to the cell boundary, the first power lines PL1, or the second power line PL2 among the patterns of the second metal layer M2. For example, the standard cell CS1 may include the via V11 connecting a cell pattern formed on the first cell track TR21 of the second metal layer M2 to the first track TR11 of the first metal layer M1. As another example, the via V11 connecting a cell pattern formed on the first cell track TR21 of the second metal layer M2 to the fifth track TR15 of the first metal layer M1, and the via V11 connecting a cell pattern formed on the fourth cell track TR24 of the second metal layer M2 to the eighth track TR18 of the first metal layer M1.

In the integrated circuit including the standard cell CS1 according to an embodiment of the present inventive concept, because a cell pattern extending outside the standard cell CS1 is not formed, and the staggered patterns SP1 are placed on the cell tracks excluding the PDN track TR2P for the PDN, for example, the first cell track TR21 and the second cell track TR22, the requirement for a maximum length of an extension pattern EX extending from a via V11, which is below the second metal layer M2, may be satisfied. In addition, because a routing pattern to be connected to the pin of the standard cell CS1 may be formed on the track for the PDN in a routing process, a degree of freedom of a routing operation may increase.

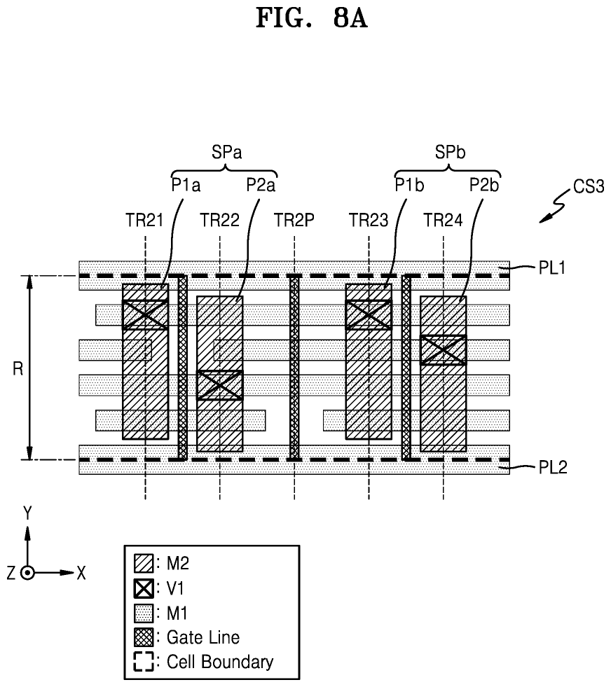

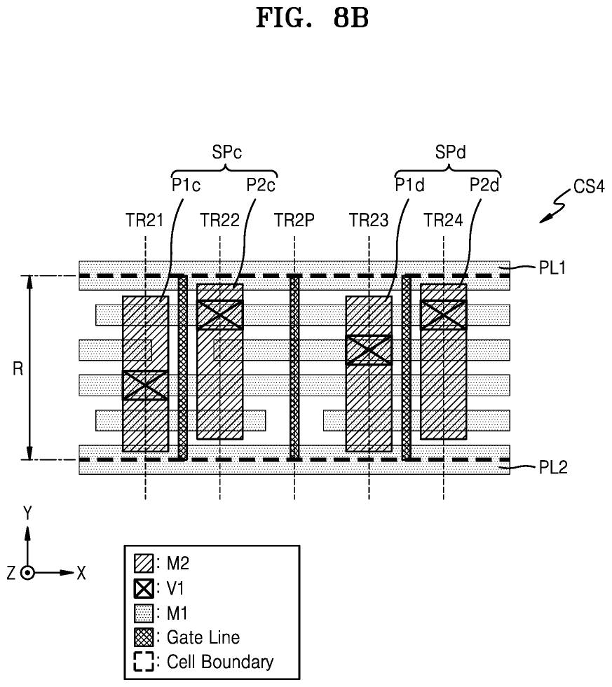

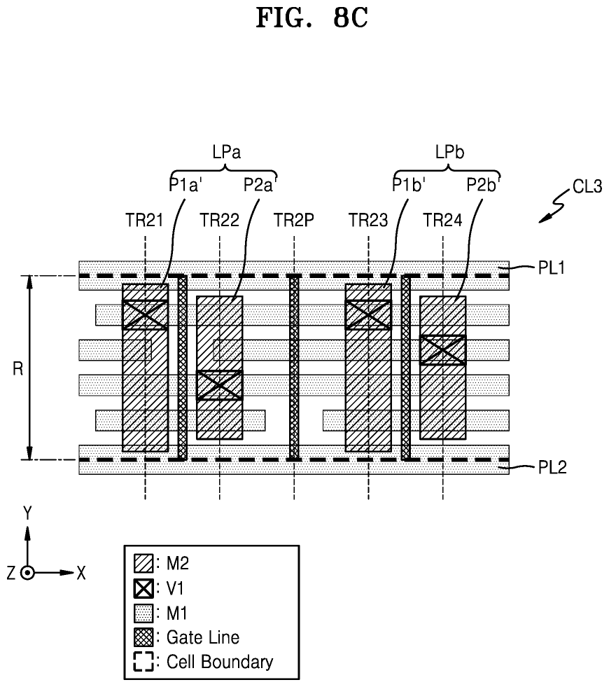

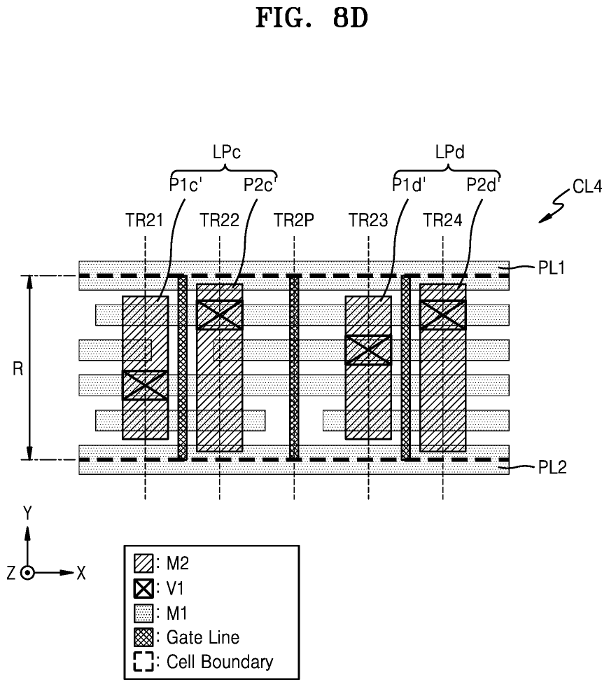

In an embodiment of the present inventive concept, the standard cell CS1 may be a multi height cell aligned and placed in continuous rows. For example, the standard cell CS1 may be continuously placed in a first row R1 having a first height and a second row R2 having a second height. At this time, the first height of the first row R1 and the second height of the second row R2 may be the same as or different from each other. However, unlike in FIG. 1, a standard cell (for example, CS3 of FIG. 8A) including the staggered pattern SP1 according to an embodiment of the present inventive concept may be a single height cell placed in one row.

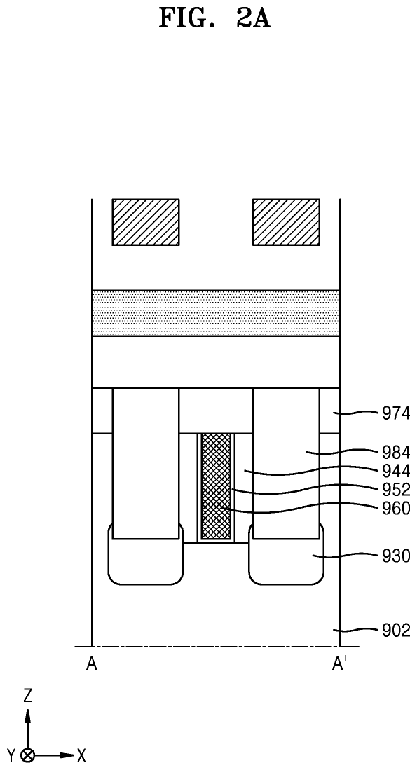

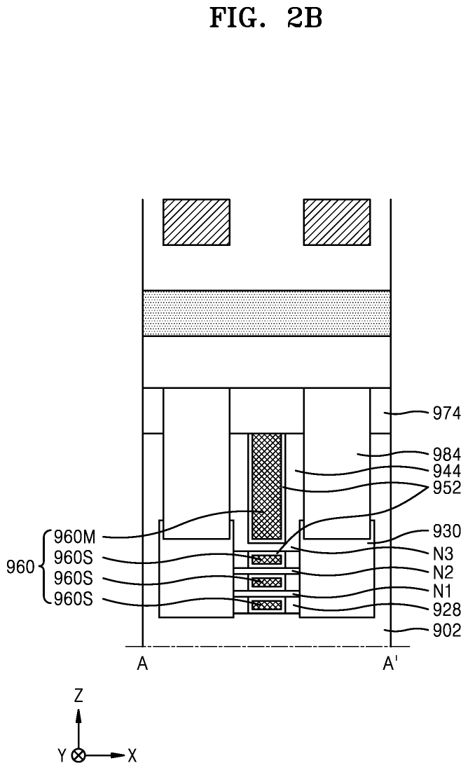

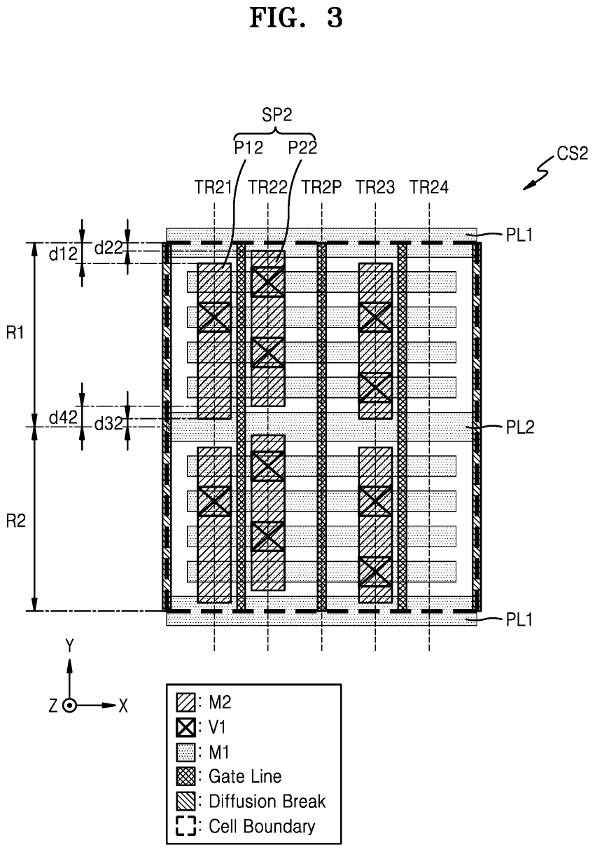

FIGS. 2A and 2B are cross-sectional views taken along the line A-A′ of FIG. 1. Although FIGS. 2A and 2B are described as examples of cross-sections of the standard cell CS1 of FIG. 1, descriptions of FIGS. 2A and 2B may be equally applied to standard cells CS2 to CS4 and CL1 to CL4 described with reference to FIG. 3.

Referring to FIGS. 1 and 2A, the standard cell CS1 may include a fin-type active region F protruding from a substrate 902 and extending in the X-axis direction. The substrate 902 may include a semiconductor such as silicon (Si) or germanium (Ge), or a III-V′ group compound such as GaAs, AlGaAs, InAs, InGaAs, InSb, GaSb, InGaSb, InP, GaP, InGaP, InN, GaN, or InGaN. In an embodiment of the present inventive concept, the substrate 902 may include a silicon-on-insulator (SOI) substrate or a germanium-on-insulator (GOI) substrate.

The number of fin-type active regions F formed in the standard cell CS1 may vary. However, the standard cell CS1 according to an embodiment of the inventive concept is not limited to that illustrated in FIGS. 2A and 2B. As illustrated in FIG. 2B, nanosheets may be formed on fin-type active regions F. For example, a multi-bridge channel (MBC) field effect transistor (FET) in which gate lines surround nanosheets may be formed. In addition, for example, a gate-all-round (GAA) FET in which nanowires are surrounded by gate lines or a vertical GAA FET in which a plurality of stacked nanowires are surrounded by gate lines may be formed on the fin-type active region F. In addition, for example, a negative capacitance (NC) FET may be formed in the active region of the standard cell CS1. In addition to the above-described examples of transistors, various transistors such as a complementary FET (CFET), a negative CFET (NCFET), a carbon nanotube (CNT) FET, a bipolar junction transistor, and other three-dimensional transistors may be formed.

The standard cell CS1 may include a plurality of gate lines 960 extending in the Y-axis direction and apart from one another in the X-axis direction. The plurality of gate lines 960 may be formed on the fin-type active region F to extend in the Y-axis direction. The plurality of gate lines 960 may include a metal, metal nitride, metal carbide, or a combination thereof. The metal may be selected from, for example, titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), and palladium (Pd). The metal nitride may be selected from TiN and TaN. The metal carbide may include TiAlC. A gate insulating layer 952 may surround each of the plurality of gate lines 960. The gate insulating layer 952 may include, for example, an interface layer and a high-k dielectric layer. The interface layer may include, for example, a silicon oxide layer, a silicon oxynitride layer, a silicate layer, or a combination thereof.

A plurality of source/drain regions 930 may be formed on the fin-type active region F. Each of the plurality of source/drain regions 930 may include an epitaxially grown semiconductor layer. For example, each of the plurality of source/drain regions 930 may include a semiconductor layer epitaxially grown from the fin-type active region F. For example, each of the plurality of source/drain regions 930 may have an embedded SiGe structure including an epitaxially grown Si layer, an epitaxially grown SiC layer, and a plurality of epitaxially grown SiGe layers. A metal silicide layer may be formed on a top surface of each of the plurality of source/drain regions 930.

A plurality of contact plugs 984 may be connected to the plurality of source/drain regions 930, respectively. The plurality of contact plugs 984 may be placed in a plurality of contact holes passing through an interlayer insulating layer 974 and an inter-gate insulating layer 944. Each of the plurality of contact plugs 984 may include a metal, conductive metal nitride, or a combination thereof. For example, each of the plurality of contact plugs 984 may include W, Cu, Al, Ti, Ta, TiN, TaN, an alloy thereof, or a combination thereof.

Referring to FIGS. 1 and 2B, the standard cell CS1 includes a plurality of fin-type active regions F protruding from a substrate 902 and a plurality of nanosheet stacks NSS facing top surfaces of the plurality of fin-type active regions F at positions spaced apart from the plurality of fin-type active regions F in the Z-axis direction. The term “nanosheet” used in the current specification refers to a conductive structure having a cross-section substantially perpendicular to a direction in which a current flows. The nanosheet should be understood to include nanowires.

Each of the plurality of nanosheet stacks NSS may include first to third nanosheets N1, N2, and N3 overlapping each other in the Z-axis direction on the top surface of each of the plurality of fin-type active regions F. Although it is illustrated in FIG. 2B that a plane of each of the plurality of nanosheet stacks NSS is substantially rectangular, the present inventive concept is not limited thereto. In addition, it is illustrated in FIG. 2B that each of the plurality of nanosheet stacks NSS includes three nanosheets. However, the present inventive concept is not limited thereto. For example, each of the plurality of nanosheet stacks NSS may include at least two nanosheets, and the number of nanosheets constituting each of the plurality of nanosheet stacks NSS is not limited thereto.

Each of the first to third nanosheets N1, N2, and N3 may include a channel region. In an embodiment of the present inventive concept, the first to third nanosheets N1, N2, and N3 may have substantially the same thickness as one another. In an embodiment of the present inventive concept, at least some of the first to third nanosheets N1, N2, and N3 may have different thicknesses from each other.

In an embodiment of the present inventive concept, the first to third nanosheets N1, N2, and N3 may include semiconductor layers including the same material as each other. For example, each of the first to third nanosheets N1, N2, and N3 may include a Si layer. For example, each of the first to third nanosheets N1, N2, and N3 may include a SiGe layer. In an embodiment of the present inventive concept, the first to third nanosheets N1, N2, and N3 may include semiconductor layers including different materials from each other. For example, the first nanosheet N1 may include a SiGe layer, and each of the second and third nanosheets N2 and N3 may include a Si layer.

Each of the plurality of gate lines 960 may at least partially surround each of the first to third nanosheets N1, N2, and N3 while covering each of the plurality of nanosheet stack NSS on each of the plurality of fin-type active regions F. Each of the plurality of gate lines 960 may include a main gate 960M and a plurality of sub-gates 960S. The main gate 960M may cover a top surface of each of the plurality of nanosheet stacks NSS and may extend in the Y-axis direction. The plurality of sub-gates 960S may be integrally connected to the main gate 960M, and may be placed among the first to third nanosheets N1, N2, and N3 and between each of the plurality of fin-type active regions F and the first nanosheet N1. The first to third nanosheets N1, N2, and N3 may be surrounded by the plurality of gate lines 960 so that a GAA structure may be obtained.

A plurality of internal insulating spacers 928 may be placed among the first to third nanosheets N1, N2, and N3 and between each of the plurality of fin-type active regions F and the first nanosheet N1. For example, the plurality of internal insulating spacers 928 may be disposed between the first to third nanosheets N1, N2, and N3. Both walls of each of the plurality of sub-gates 960S may be covered with each of the plurality of internal insulating spacers 928 with the gate insulating layer 952 therebetween.

FIG. 3 is a layout diagram illustrating a standard cell CS2 placed in an integrated circuit according to an embodiment of the present inventive concept. In FIG. 3, description previously given with reference to FIG. 1 is omitted.

Referring to FIG. 3, the standard cell CS2 may include a second metal layer M2 in which a plurality of tracks are defined. The plurality of tracks may include cell tracks (for example, TR21 to TR24), on which cell patterns are formed, and at least one PDN track TR2P, on which a PDN pattern or a routing pattern is formed. For example, the first to fourth cell tracks TR21 to TR24 and the PDN track TR2P may be formed in the standard cell CS2. Cell patterns might not be formed on some (for example, the fourth cell track TR24) of the first to fourth cell tracks TR21 to TR24. Cell patterns may be repeatedly formed on the first to fourth cell tracks TR21 to TR24 based on the PDN track TR2P. For example, the first cell track TR21 and the third cell track TR23 may include cell patterns formed in the same manner.

The standard cell CS2 may include the patterns of the first metal layer M1 and the second metal layer M2. For example, the standard cell CS2 may include at least one staggered pattern SP2 formed on the second metal layer M2. A staggered pattern SP2 placed in a first row R1 may include, for example, a first cell pattern P12, which is formed on the first cell track TR21, and a second cell pattern P22, which is formed on the second cell track TR22, and the first cell pattern P12 and the second cell pattern P22 may be adjacent to each other in the X-axis direction. The first cell pattern P12 may be spaced apart from a cell boundary by a first length d12, and the second cell pattern P22 may be spaced apart from the cell boundary by a second length d22. For example, the first cell pattern P12 may be spaced apart from a first power line PL1 by the first length d12 and the second cell pattern P22 may be spaced apart from the first power line PL1 by the second length d22. In addition, the first cell pattern P12 may be spaced apart from a second power line PL2 by a third length d32, and the second cell pattern P22 may be apart from the second power line PL2 by a fourth length d42. At this time, the first length d12 may be greater than the second length d22, and the third length d32 may be less than the fourth length d42. In an embodiment of the present inventive concept, the first cell pattern P12 formed on the first cell track TR21 and the second cell pattern P22 formed on the second cell track TR22 may have the same length as each other.

The standard cell CS2 may further include a staggered pattern SP2 placed in a second row R2 and formed on the second metal layer M2. The patterns of the second metal layer M2 may be spaced apart from one another at designated intervals. Because the standard cell CS2 includes the staggered pattern SP2 in each of the first row R1 and the second row R2, the tip-to-tip space requirement in the second metal layer M2 may be satisfied.

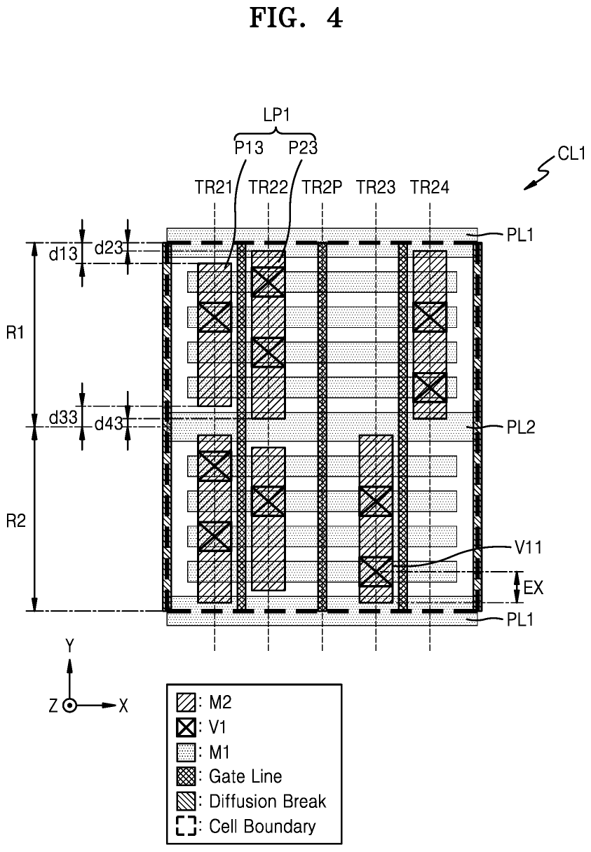

FIG. 4 is a layout diagram illustrating a standard cell CL1 placed in an integrated circuit according to an embodiment of the present inventive concept. In FIG. 4, description previously given with reference to FIG. 1 is omitted.

Referring to FIG. 4, the standard cell CL1 may include a second metal layer M2 in which a plurality of tracks are defined. The plurality of tracks may include cell tracks (for example, TR21 to TR24), on which cell patterns are formed, and at least one PDN track TR2P, on which a PDN pattern or a routing pattern is formed. For example, the first to fourth cell tracks TR21 to TR24 and the PDN track TR2P may be formed in the standard cell CL1.

The standard cell CL1 may include at least one long short pattern LP1 formed on the second metal layer M2. The long short pattern LP1 placed in a first row R1 may include, for example, a first cell pattern P13, which is formed on the first cell track TR21, and a second cell pattern P23, which is formed on the second cell track TR22. The first cell pattern P13 and the second cell pattern P23 may be adjacent to each other in the X-axis direction, and a length of the first cell pattern P13 may be less than that of the second cell pattern P23.

The first cell pattern P13 may be spaced apart from a cell boundary by a first length d13, and the second cell pattern P23 may be spaced apart from the cell boundary by a second length d23. For example, the first cell pattern P13 may be spaced apart from a first power line PL1 by the first length d13 and the second cell pattern P23 may be spaced apart from the first power line PL1 by the second length d23. In addition, the first cell pattern P13 may be spaced apart from a second power line PL2 by a third length d33, and the second cell pattern P23 may be spaced apart from the second power line PL2 by a fourth length d43. For example, the first length d13 may be greater than the second length d23, and the third length d33 may be greater than the fourth length d43.

The standard cell CL1 may further include a long short pattern LP1 placed in a second row R2 and formed on the second metal layer M2. The long short pattern LP1 placed in the second row R2 may include the first cell pattern P13, which is placed in the first cell track TR21, and the second cell pattern P23, which is placed in the second cell track TR22, and a length of the first cell pattern P13 may be greater than that of the second cell pattern P23. Because the standard cell CL1 includes the long short pattern LP1 in each of the first row R1 and the second row R2, the tip-to-tip space requirement in the second metal layer M2 may be satisfied.

Cell patterns may be repeatedly formed on the first to fourth cell tracks TR21 to TR24 based on the PDN track TR2P. For example, the first cell track TR21 and the third cell track TR23 may include patterns of the same shape, or the second cell track TR22 and the fourth cell track TR24 may include patterns of the same shape.

The standard cell CL1 may include a plurality of first vias V1 electrically connected between the patterns of the first metal layer M1 and the patterns of the second metal layer M2. In an embodiment of the present inventive concept, the plurality of first vias V1 included in the standard cell CL1 may include vias V11 connected to patterns formed on tracks closest to the cell boundary among the plurality of tracks of the first metal layer M1, or tracks closest to the first power lines PL1 or the second power line PL2. At this time, the vias V11 may be connected to patterns of which tips are closer to the cell boundary, the first power lines PL1, or the second power line PL2 among the patterns of the second metal layer M2. For example, the standard cell CL1 may include the via V11 connecting a cell pattern formed on the second cell track TR22 of the second metal layer M2 to the first track of the first metal layer M1, and the via V11 connecting a cell pattern formed on the third cell track TR23 of the second metal layer M2 to the eighth track of the first metal layer M1. Accordingly, the requirement for a minimum length of the extension pattern EX extending from the via V11, which is below the second metal layer M2, may be satisfied.

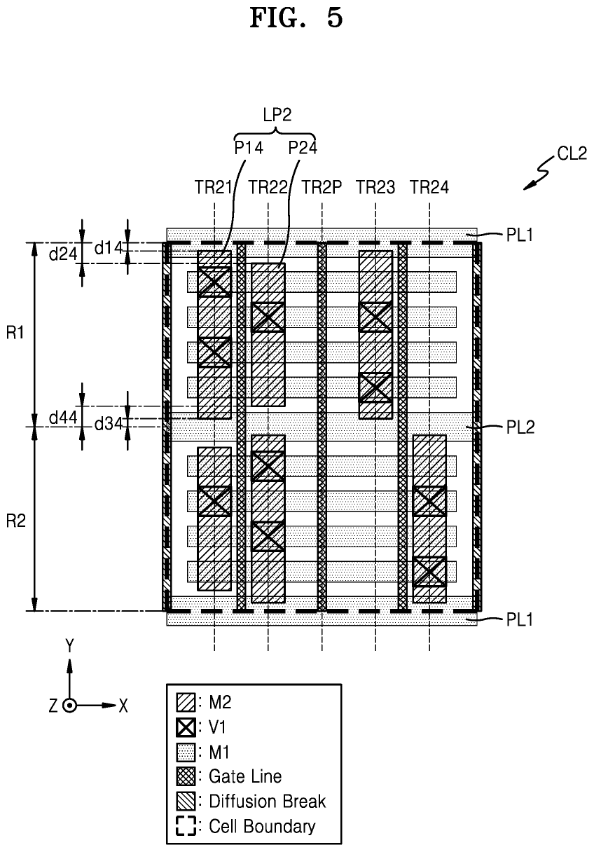

FIG. 5 is a layout diagram illustrating a standard cell CL2 placed in an integrated circuit according to an embodiment of the present inventive concept. In FIG. 5, description previously given with reference to FIGS. 1 and 4 is omitted.

Referring to FIG. 5, the standard cell CL2 may include a second metal layer M2, in which a plurality of tracks are defined. The plurality of tracks may include cell tracks (for example, TR21 to TR24), on which cell patterns are formed, and at least one PDN track TR2P, on which a PDN pattern or a routing pattern is formed. For example, the first to fourth cell tracks TR21 to TR24 and the PDN track TR2P may be formed in the standard cell CL2.

The standard cell CL2 may include at least one long short pattern LP2 formed on the second metal layer M2. The long short pattern LP2 placed in a first row R1 may include, for example, a first cell pattern P14, which is formed on the first cell track TR21, and a second cell pattern P24, which is formed on the second cell track TR22. The first cell pattern P14 and the second cell pattern P24 may be adjacent to each other in the X-axis direction, and a length of the first cell pattern P14 may be greater than that of the second cell pattern P24.

The first cell pattern P14 may be spaced apart from a cell boundary by a first length d14, and the second cell pattern P24 may be spaced apart from the cell boundary by a second length d24. For example, the first cell pattern P14 may be spaced apart from a first power line PL1 by the first length d14, and the second cell pattern P24 may be spaced apart from the first power line PL1 by the second length d24. In addition, the first cell pattern P14 may be spaced apart from a second power line PL2 by a third length d34, and the second cell pattern P24 may be spaced apart from the second power line PL2 by a fourth length d44. The first length d14 may be less than the second length d24, and the third length d34 may be less than the fourth length d44.

The standard cell CL2 may further include a long short pattern LP2 placed in a second row R2 and formed on the second metal layer M2. The long short pattern LP2 placed in the second row R2 may include the first cell pattern P14, which is placed in the first cell track TR21, and the second cell pattern P24, which is placed in the second cell track TR22, and a length of the first cell pattern P14 may be less than that of the second cell pattern P24. Because the standard cell CL2 includes the long short pattern LP2 in each of the first row R1 and the second row R2, the tip-to-tip space requirement in the second metal layer M2 may be satisfied.

Cell patterns may be repeatedly formed on the first to fourth cell tracks TR21 to TR24 based on the PDN track TR2P. For example, the first cell track TR21 and the third cell track TR23 may include patterns of the same shape, or the second cell track TR22 and the fourth cell track TR24 may include patterns of the same shape. However, the present inventive concept is not limited thereto. For example, the first cell track TR21 and the third cell track TR23 may include patterns of different shapes, or the second cell track TR22 and the fourth cell track TR24 may include patterns of different shapes.

In FIGS. 1 and 3 to 5, the standard cells CS1 and CS2 including the staggered patterns SP1 and SP2 or the standard cells CL1 and CL2 including the long short patterns LP1 and LP2 have been described. However, the standard cell according to embodiments of the present inventive concept is not limited thereto. The standard cell according to an embodiments of the present inventive concept may include at least one of the staggered patterns SP1 and SP2 and the long short patterns LP1 and LP2.

FIG. 6 is a flowchart illustrating a method of manufacturing an integrated circuit, according to an embodiment of the present inventive concept.

Referring to FIG. 6, a standard cell library D10 may include information on standard cells, for example, function information, characteristic information, and layout information. The standard cell library D10 may include data DC defining layouts of standard cells. The data DC may define structures of standard cells performing the same function and having different layouts. The data DC may define structures of the standard cells CS1, CS2, CL1, and CL2 described with reference to FIGS. 1 to 5 or the standard cells CS3, CS4, CL3, and CL4 described with reference to FIGS. 8A to 8D. The data DC may include first data DC1, which defines structures of standard cells performing a first function and has different layouts, and nth data DCn (n is a natural number greater than or equal to 2), which defines structures of standard cells performing an nth function and has different layouts. For example, the standard cells CS1, CS2, CL1, and CL2 described with reference to FIGS. 1 to 5 may perform the same function and may have different layouts, and data defining the standard cells CS1, CS2, CL1, and CL2 described with reference to FIGS. 1 to 5 may be included in the standard cell library D10.

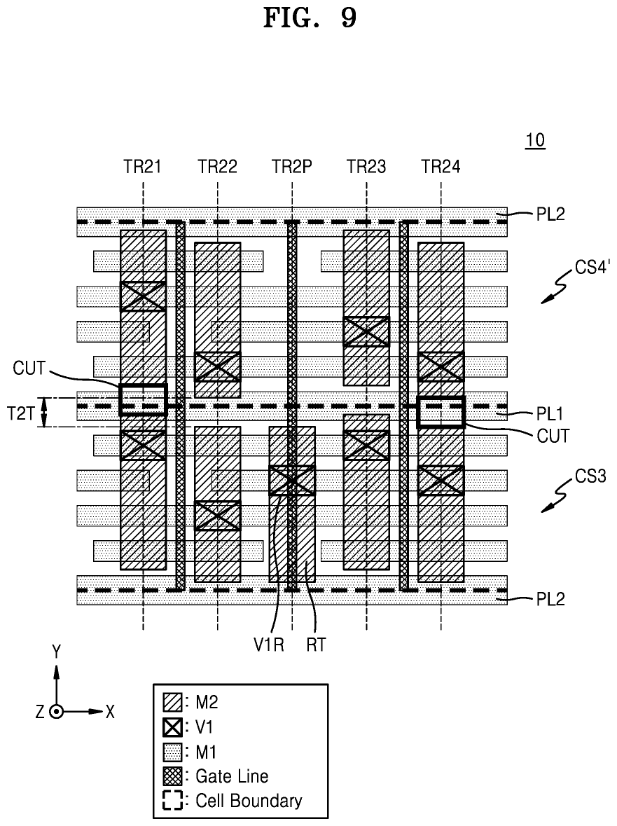

In operations S10 and S20 of designing the integrated circuit, layout data D30 may be generated from RTL data D11. The integrated circuit may include at least one of the standard cells CS1, CS2, CL1, and CL2 described with reference to FIGS. 1 to 5 or the standard cells CS3, CS4, CL3, and CL4 described with reference to FIGS. 8A to 8D. In addition, the integrated circuit may include one of integrated circuits 10, 10A, and 10B to be described with reference to FIGS. 9 to 11.

In operation S10, a logic synthesis operation of generating netlist data D20 from the RTL data D11 may be performed. For example, a semiconductor design tool (for example, a logic synthesis module) may generate the netlist data D20 including a bitstream or a netlist by performing logic synthesis from the RTL data D11 written in a hardware description language (HDL) such as a VHSIC HDL (VHDL) and Verilog with reference to the standard cell library D10. The standard cell library D10 may include the data DC defining structures of standard cells performing the same function and having different layouts, and standard cells may be included in the integrated circuit with reference to such information in a logic synthesis process.

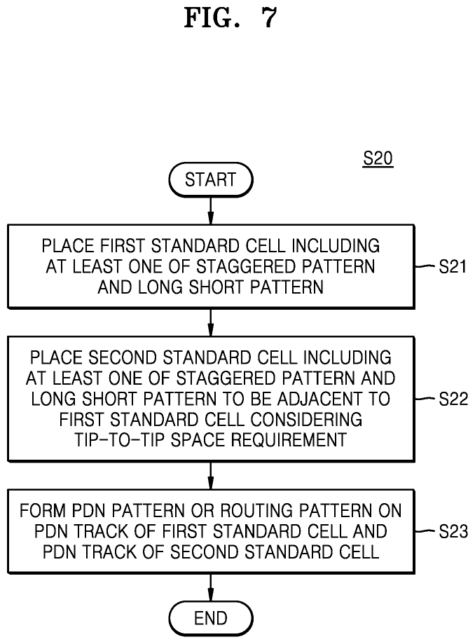

In operation S20, a place and routing process of generating the layout data D30 from the netlist data D20 may be performed. The layout data D30 may have a format such as GDSII and may include geometric information on standard cells and interconnections. In an embodiment of the present inventive concept, operation S20 may include operations S21 to S23 of FIG. 7.

In operation S20, a semiconductor design tool (for example, a place and routing module) may place a plurality of standard cells from the netlist data D20 with reference to the standard cell library D10. The semiconductor design tool may select one of layouts of standard cells defined by a netlist with reference to the data DC, and may place the selected layout of the standard cell.

In operation S20, at least one of the standard cells CS1, CS2, CL1, CL2 described with reference to FIGS. 1 to 5 or standard cells CS3, CS4, CL3, and CL4 to be described with reference to FIGS. 8A to 8D may be placed, and standard cells obtained by flipping the standard cells CS1, CS2, CL1, and CL2 described with reference to FIGS. 1 to 5 in the X axis may be placed, and standard cells obtained by flipping the standard cells CS3, CS4, CL3, and CL4 to be described with reference to FIGS. 8A to 8D in the X axis may be placed.

In addition, in operation S20, the semiconductor design tool may perform a routing operation of generating interconnections. “Routing” may be an operation of arranging wiring layers and vias for properly connecting placed standard cells in accordance with design rules for an integrated circuit. The interconnection may electrically connect an output pin of a standard cell to an input pin of a standard cell, and may include, for example, a conductive pattern formed in at least one via and at least one metal layer. Patterns formed on different levels of metal layers may be electrically connected to one another through vias including conductive materials. In this case, the metal layers may include a metal as a conductive material.

In operation S30, optical proximity correction (OPC) may be performed. The OPC may refer to a job to form a pattern of a desired shape by correcting distortion such as refraction due to light characteristics in photolithography included in semiconductor processes for manufacturing an integrated circuit, and a pattern on a mask may be determined by applying the OPC to layout data D30. In an embodiment of the present inventive concept, a layout of the integrated circuit may be limitedly modified in operation S30, and the limited modification of the integrated circuit in operation S30 is a post-processing for optimizing a structure of the integrated circuit. The limited modification of the integrated circuit may be referred to as design polishing.

In operation S40, an operation of manufacturing a mask may be performed. For example, as the OPC is applied to the layout data D30, patterns on a mask may be defined to form patterns on a plurality of layers, and at least one mask (or photomask) may be manufactured to form patterns for the plurality of layers.

In operation S50, an operation of manufacturing the integrated circuit may be performed. For example, the integrated circuit may be manufactured by patterning a plurality of layers by using at least one mask manufactured in operation S40. Operation S50 may include operations S51, S53, and S55, and may include a deposition process, an etching process, an ion process, and a cleaning process. In addition, operation S50 may include a packaging process of mounting a semiconductor device on a printed circuit board (PCB) and sealing the semiconductor device with a sealant, or a test process of testing the semiconductor device or package.

In operation S51, a front-end-of-line (FEOL) process may be performed. The FEOL may refer to a process of forming individual devices, for example, a transistor, a capacitor, and a resistor on a substrate in manufacturing processes of the integrated circuit. For example, the FEOL may include planarizing and cleaning a wafer, forming a trench, forming a well, forming a gate line, and forming source and drain regions.

In operation S53, a middle-of-line (MOL) process may be performed. The MOL process may refer to a process of forming a connection member for connecting the individual devices generated through the FEOL process in a standard cell. For example, the MOL process may include forming an active contact on an active region, forming a gate contact on a gate line, and forming a via on the active contact and the gate line.

In operation S55, a back-end-of-line (BEOL) process may be performed. The BEOL may refer to a process of interconnecting the individual devices, for example, the transistor, the capacitor, and the resistor on the substrate in the manufacturing processes of the integrated circuit. For example, the BEOL may include siliciding gate, source, and drain regions, adding a dielectric, planarization, forming holes, forming metal layers, forming a via between metal layers, and forming a passivation layer. The integrated circuit may be packaged in a semiconductor package and may be used as a component of one of various applications.

FIG. 7 is a flowchart illustrating a method of manufacturing an integrated circuit, according to an embodiment of the present inventive concept. Operation S20 of FIG. 7 as an embodiment of operation S20 of FIG. 6, may include operations S21 to S23.

Referring to FIG. 7, in operation S21, a first standard cell including at least one of a staggered pattern and a long short pattern may be placed. For example, the first standard cell may include staggered patterns of the standard cells CS1 and CS2 described with reference to FIGS. 1 and 3, or long short patterns of the standard cells CL1 and CL2 described with reference to FIGS. 4 and 5.

For example, each of the staggered patterns may include a first pattern and a second pattern having the same length as each other. The first pattern of each of the staggered patterns may be formed on a first cell track among a plurality of cell tracks of a second metal layer and may be spaced apart from a cell boundary of the first standard cell by a first length. The second pattern of each of the staggered patterns may be formed on a second cell track adjacent to the first cell track among a plurality of cell tracks and may be spaced apart from the cell boundary of the first standard cell by a second length that is different from the first length.

For example, each of the long short patterns may include a first pattern and a second pattern having different lengths from each other. The first pattern of each of the long short patterns may be formed on a first cell track among a plurality of cell tracks of a second metal layer and may be spaced apart from a cell boundary of the first standard cell by a first length. The second pattern of each of the long short patterns may be formed on a second cell track adjacent to the first cell track among a plurality of cell tracks and may be spaced apart from the cell boundary of the first standard cell by a second length that is different from the first length.

In operation S22, considering the tip-to-tip space requirement, a second standard cell including at least one of the staggered patterns and/or the long short patterns may be placed adjacent to the first standard cell. In this case, the second standard cell may be adjacent to the first standard cell in the Y-axis direction in which the plurality of tracks of the second metal layer extend. For example, when the first standard cell includes a pattern that is relatively close to the cell boundary on the first cell track, a second standard cell, which includes a pattern that is relatively far from the cell boundary on the first cell track, may be placed to contact the cell boundary. Because the first standard cell, which includes the staggered patterns or the long short patterns, and the second standard cell, which includes the staggered patterns or the long short patterns, are adjacent to each other, the integrated circuit according to an embodiment of the present inventive concept may satisfy the tip-to-tip space requirement.

In operation S23, a PDN pattern or a routing pattern may be formed on a PDN track of the first standard cell and a PDN track of the second standard cell. The PDN track of the first standard cell and the PDN track of the second standard cell may be defined in a metal layer on which the staggered patterns or the long short patterns are formed in the first standard cell and the second standard cell. Because the cell pattern of the first standard cell is not formed on the PDN track of the first standard cell and the cell pattern of the second standard cell is not formed on the PDN track of the second standard cell, the routing pattern may be formed on the PDN track when routing to be connected to the input/output pin of the first standard cell or the second standard cell is required. When routing to be connected to the input/output pin of the first standard cell or the second standard cell is not required, a PDN pattern may be formed on the PDN track.

FIGS. 8A to 8D are layout diagrams illustrating standard cells CS3, CS4, CL3, and CL4 placed in an integrated circuit according to an embodiment of the present inventive concept. In FIGS. 8A to 8D, descriptions that may be redundant or repetitive with descriptions for FIGS. 1 and 4 may be omitted or briefly discussed. FIGS. 8A to 8D illustrate parts of the first to fourth standard cells CS3, CS4, CL3, and CL4.

A cell boundary of each of the first to fourth standard cells CS3, CS4, CL3, and CL4 is defined by a first power line PL1 and a second power line PL2. The first to fourth standard cells CS3, CS4, CL3, and CL4 are described as single height cells placed in one row R having a specific height. However, the present inventive concept is not limited thereto, and the first to fourth standard cells CS3, CS4, CL3, and CL4 may be multi-height cells. In the second metal layer M2, first to fourth cell tracks TR21 to TR24, on which cell patterns are formed, and a PDN track, on which a PDN pattern or a routing pattern is formed may be defined.

Referring to FIG. 8A, the first standard cell CS3 may include staggered patterns formed on the second metal layer M2. For example, the first standard cell CS3 may include a first staggered pattern Spa, which is formed on the first cell track TR21 and the second cell track TR22, and a second staggered pattern SPb, which is formed on the third cell track TR23 and the fourth cell track TR24.

The first staggered pattern SPa may include a first pattern P1a, which is close to the first power line PL1, and a second pattern P2a, which is close to the second power line PL2. For example, of the first pattern P1a and the second pattern P2a, the first pattern P1a may be closer to the first power line PL1. As another example, of the first pattern P1a and the second pattern P2a, the second pattern P2a may be closer to the second power line PL2. In an embodiment of the present inventive concept, the first pattern P1a and the second pattern P2a have the same length as each other. However, the present inventive concept is not limited thereto, and the first pattern P1a and the second pattern P2a may have different lengths from each other.

The second staggered pattern SPb may include a first pattern P1b, which is close to the first power line PL1, and a second pattern P2b, which is close to the second power line PL2. For example, of the first pattern P1b and the second pattern P2b, the first pattern P1b may be closer to the first power line PL1. As another example, of the first pattern P1b and the second pattern P2b, the second pattern P2b may be closer to the second power line PL2. In an embodiment of the present inventive concept, the first pattern P1b and the second pattern P2b have the same length as each other. However, the present inventive concept is not limited thereto, and the first pattern P1b and the second pattern P2b may have different lengths from each other.

In an embodiment of the present inventive concept, the first staggered pattern SPa and the second staggered pattern SPb might not be aligned with a gate line in the Z-axis direction. The PDN track TR2P may be aligned with the gate line in the Z-axis direction.

In an embodiment of the present inventive concept, the staggered patterns may be repeatedly placed based on the PDN track TR2P. For example, the first staggered pattern SPa and the second staggered pattern SPb may be formed in the same manner. In addition, in an embodiment of the present inventive concept, the standard cell CS3 may include a plurality of PDN tracks TR2P, and the plurality of PDN tracks TR2P may be placed at specific intervals (for example, twice an interval between gate lines).

Referring to FIGS. 8A and 8B, the second standard cell CS4 may include staggered patterns formed on the second metal layer M2. For example, the second standard cell CS4 may include a first staggered pattern SPc, which is formed on the first cell track TR21 and the second cell track TR22, and a second staggered pattern SPd, which is formed on the third cell track TR23 and the fourth cell track TR24.

The first staggered pattern SPc may include a first pattern P1c, which is close to the second power line PL2, and a second pattern P2c, which is close to the first power line PL1. In an embodiment of the present inventive concept, the first pattern P1c and the second pattern P2c have the same length as each other. However, the present inventive concept is not limited thereto, and the first pattern P1c and the second pattern P2c may have different lengths from each other.

The second staggered pattern SPd may include a first pattern P1d, which is close to the second power line PL2, and a second pattern P2d, which is close to the first power line PL1. In an embodiment of the present inventive concept, the first pattern P1d and the second pattern P2d have the same length as each other. However, the present inventive concept is not limited thereto, and the first pattern P1d and the second pattern P2d may have different lengths from each other.

The first standard cell CS3 and the second standard cell CS4 as a pair may be placed in an integrated circuit. Because the cell patterns formed on the second metal layer M2 are symmetrical with respect to the X-axis in the first standard cell CS3 and the second standard cell CS4, in the integrated circuit, one of the first standard cell CS3 and the second standard cell CS4 may be flipped in the X-axis and may be placed adjacent to another standard cell in the Y-axis direction so that the tip-to-tip space requirement may be satisfied.

Referring to FIG. 8C, the third standard cell CL3 may include long short patterns formed on the second metal layer M2. For example, the third standard cell CL3 may include a first long short pattern LPa, which is formed on the first cell track TR21 and the second cell track TR22, and a second long short pattern LPb, which is formed on the third cell track TR23 and the fourth cell track TR24.

The first long short pattern LPa may include a first pattern P1a′, which is close to the first power line PL1 and the second power line PL2, and a second pattern P2a′, which is far from the first power line PL1 and the second power line PL2. A length of the first pattern P1a′ may be greater than that of the second pattern P2a′.

The second long short pattern LPb may include a first pattern P1b′, which is close to the first power line PL1 and the second power line PL2, and a second pattern P2b′, which is far from the first power line PL1 and the second power line PL2. A length of the first pattern P1b′ may be greater than that of the second pattern P2b′.

Referring to FIGS. 8C and 8D, the fourth standard cell CL4 may include long short patterns formed on the second metal layer M2. For example, the fourth standard cell CL4 may include a first long short pattern LPc, which is formed on the first cell track TR21 and the second cell track TR22, and a second long short pattern LPd, which is formed on the third cell track TR23 and the fourth cell track TR24. The first long short pattern LPc may include a first pattern P1c′ and a second pattern P2c′ that is longer than the first pattern P1c′, and the second long short pattern LPd may include a first pattern P1d′ and a second pattern P2d′ that is longer than the first pattern P1d′.

The third standard cell CL3 and the fourth standard cell CS4 as a pair may be placed in an integrated circuit. When a long pattern P1a‘ or P1b’ is placed on a specific track of the third standard cell CL3, a short pattern P1c‘ or P1d’ is placed on the specific track of the fourth standard cell CL4. When a long pattern P2c′ or P2d′ is placed on a specific track of the fourth standard cell CL4, a short pattern P2a′ or P2b′ is placed on the specific track of the third standard cell CL3. Therefore, in the integrated circuit, the third standard cell CL3 and the fourth standard cell CL4 may be placed adjacent to each other in the Y-axis direction and the tip-to-tip space requirement may be satisfied.

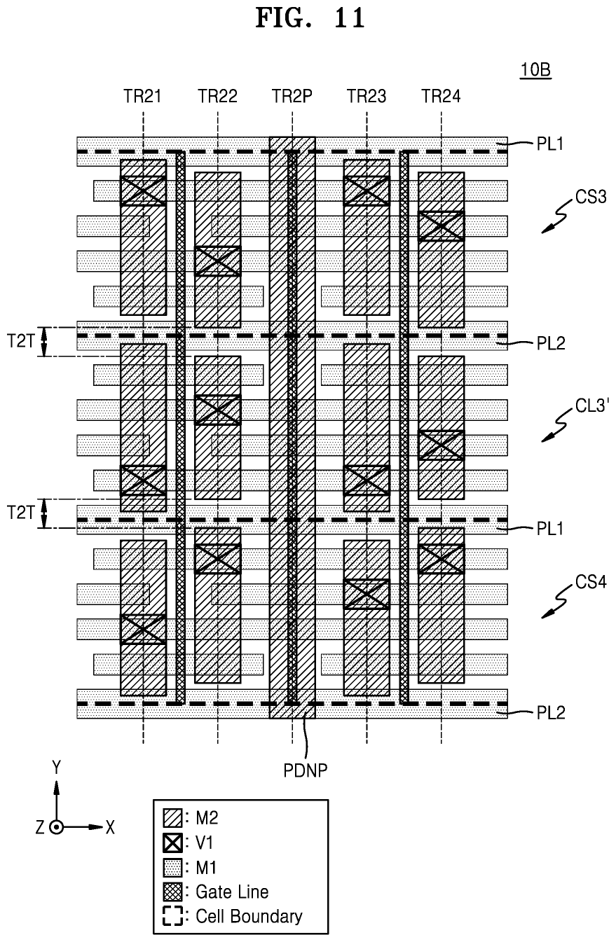

FIGS. 9 to 11 are layout diagrams of integrated circuits 10, 10A, and 10B according to an embodiment of the present inventive concept. FIGS. 9 and 11 are diagrams for describing the place and routing operation S20 of FIGS. 6 and 7.

Referring to FIG. 9, the integrated circuit 10 may include a first standard cell CS3 and a second standard cell CS4′ adjacent to each other in the Y-axis direction. The first standard cell CS3 may be the first standard cell CS3 of FIG. 8A, and the second standard cell CS4′ may be a standard cell including patterns in which the second standard cell CS4 of FIG. 8B is flipped in the X-axis. Because each of the first standard cell CS3 and the second standard cell CS4′ includes the staggered patterns, the tip-to-tip space T2T requirement may be satisfied in the first to fourth cell tracks TR21 to TR24.

In an embodiment of the present inventive concept, two patterns formed on the first cell track TR21 or the fourth cell track TR24, which are to be adjacent to each other, may be formed separately while satisfying the tip-to-tip space T2T requirement as a cut region CUT. When a pattern is separated by the cut region CUT, a tip of the pattern may be concave.

In addition, in an embodiment of the present inventive concept, two patterns formed on the second cell track TR22 or the third cell track TR23, which are to be adjacent to each other, may be spaced apart from each other while satisfying the tip-to-tip space T2T requirement. When two adjacent patterns are separately formed, tips of the patterns may be convex.

In an embodiment of the present inventive concept, in the PDN track TR2P of the integrated circuit 10, a routing pattern RT and a via V1R electrically connecting the routing pattern RT to a lower pattern may be formed. For example, the routing pattern RT may be electrically connected to the input/output pin of the first standard cell CS3, and may electrically connect the first standard cell CS3 to another standard cell. For example, the routing pattern RT may be electrically connected to a gate line of the first standard cell CS3 through the via V1R, the first metal layer, and a contact that is disposed under the first metal layer.

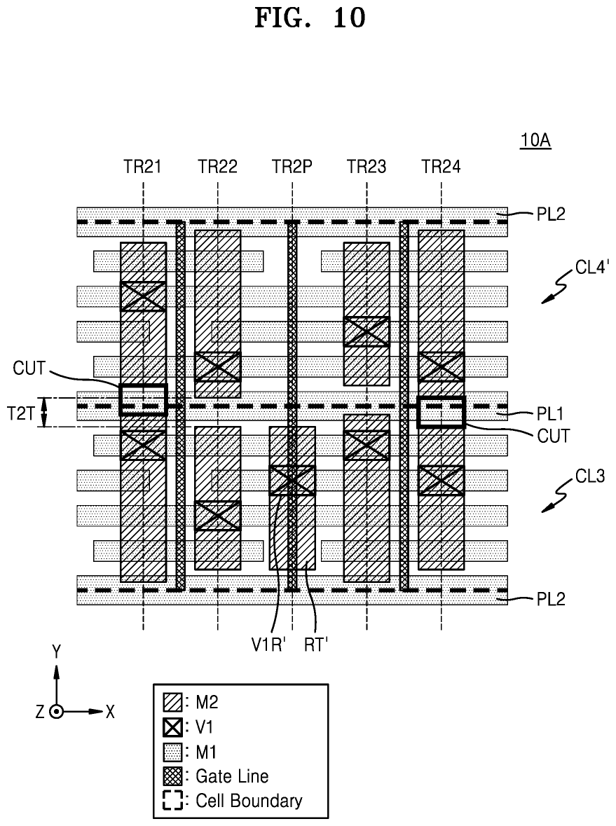

Referring to FIG. 10, the integrated circuit 10A may include a third standard cell CL3 and a fourth standard cell CL4′ adjacent to each other in the Y-axis direction. The third standard cell CL3 may be the third standard cell CL3 of FIG. 8C, and the fourth standard cell CL4′ may be a standard cell including patterns in which the fourth standard cell CL4 of FIG. 8D is flipped in the X-axis. Because each of the third standard cell CL3 and the fourth standard cell CL4′ includes long short patterns, the tip-to-tip space T2T requirement may be satisfied in the first to fourth cell tracks TR21 to TR24.

In an embodiment of the present inventive concept, in the PDN track TR2P of the integrated circuit 10A, a routing pattern RT′ and a via V1R′ electrically connecting the routing pattern RT′ to a lower pattern may be formed. For example, the routing pattern RT′ may be electrically connected to the input/output pin of the third standard cell CL3, and may electrically connect the third standard cell CL3 to another standard cell.

Referring to FIG. 11, the integrated circuit 10B may include a second standard cell CS4, a third standard cell CL3′, and a first standard cell CS3 adjacent to each other in the Y-axis direction. The first standard cell CS3 may be the first standard cell CS3 of FIG. 8A. The second standard cell CS4 may be the second standard cell CS4 of FIG. 8B, and the third standard cell CL3 may be a standard cell including patterns in which the third standard cell CL3 of FIG. 8C is flipped in the X-axis.

Because patterns that are close to the first power line PL1 are formed on the second cell track TR22 and the fourth cell track TR24 in the second standard cell CS4, and patterns that are close to the second power line PL2 are formed on the second cell track TR22 and the fourth cell track TR24 in the first standard cell CS3, by placing the third standard cell CL3′ including the long short patterns between the first standard cell CS3 and the second standard cell CS4, the tip-to-tip space T2T requirement may be satisfied. For example, because the third standard cell CL3′ includes short patterns in the second cell track TR22 and the fourth cell track TR24, the tip-to-tip space T2T requirement may be easily satisfied.

In an embodiment of the present inventive concept, a PDN pattern PDNP may be placed on the PDN track TR2P of the integrated circuit 10B. The PDN pattern PDNP may cross the second standard cell CS4, the third standard cell CL3′, and the first standard cell CS3. The PDN pattern PDNP may be electrically connected to the first power line PL1 or the second power line PL2.

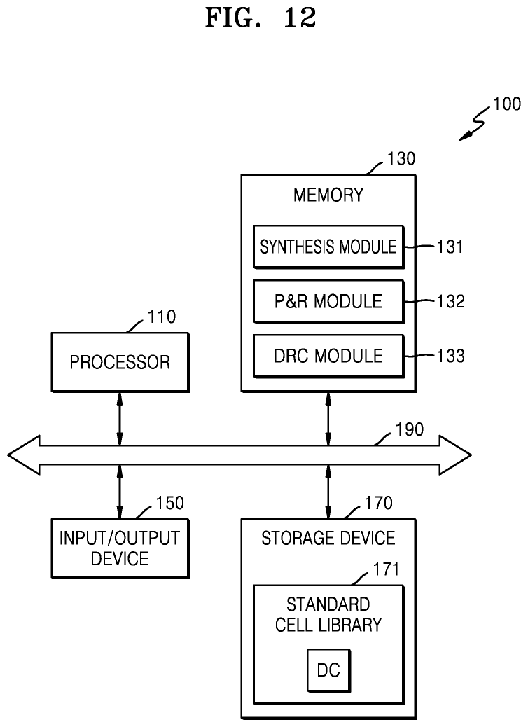

FIG. 12 is a block diagram illustrating a computing system 100 for designing an integrated circuit according to an embodiment of the present inventive concept.

Referring to FIG. 12, the computing system 100 for designing an integrated circuit (hereinafter, referred to as an “integrated circuit design system”) 100 may include a processor 110, memory 130, an input/output device 150, a storage device 170, and a bus 190. The integrated circuit design system 100 may perform an integrated circuit design operation including operations S10 and S20 of FIG. 6, and may perform an integrated circuit design operation including operations S21 to S23 of FIG. 7. In an embodiment of the present inventive concept, the integrated circuit design system 100 may be implemented as an integrated device, and thus may be referred to as an integrated circuit design device. The integrated circuit design system 100 may be provided as a dedicated device for designing an integrated circuit of a semiconductor device, but may be a computer for driving various simulation tools or design tools.

The integrated circuit design system 100 may include a fixed computing system such as a desktop computer, a workstation, or a server, or a portable computing system such as a laptop computer.

The processor 110 may execute instructions performing at least one of various operations for designing the integrated circuit. For example, the processor 110 may include a core that may execute any set of instructions (for example, Intel Architecture-32 (IA-32), 64-bit extension IA-32, x86-64, PowerPC, Sparc, MIPS, ARM, and IA-64) such as a microprocessor, an application processor (AP), a digital signal processor (DSP), or a graphics processing unit (GPU). The processor 110 may communicate with the memory 130, the input/output device 150, and the storage device 170 through the bus 190. The processor 110 may perform the integrated circuit design operation by driving a synthesis module 131 loaded on the memory 130, a place and routing module 132, and a design rule check (DRC) module 133.

The memory 130 may store the synthesis module 131, the place and routing module 132, and the DRC module 133. The synthesis module 131, the place and routing module 132, and the DRC module 133 may be loaded from the storage device 170 to the memory 130. The synthesis module 131 may include, for example, a program including a plurality of instructions for performing the logic synthesis operation in operation S10 of FIG. 6. The place and routing module 132 may include, for example, a program including a plurality of instructions for performing a layout design operation in operation S20 of FIG. 6.

The DRC module 133 may determine whether a design rule error exists. The DRC module 133 may include, for example, a program including a plurality of instructions for performing a DRC operation. When there is a design rule violation, the place and routing module 132 may adjust a layout of a placed cell. When there is no design rule error, integrated circuit layout design may be completed. In an embodiment of the present inventive concept, the DRC module 133 may determine whether patterns formed on defined tracks on a specific metal layer satisfy the tip-to-tip space requirement. In addition, in an embodiment of the present inventive concept, the DRC module 133 may determine whether requirement for a minimum length of an extension pattern extending from a via below a specific metal layer is satisfied.

The memory 130 may include volatile memory such as static random access memory (SRAM) or dynamic RAM (DRAM), or non-volatile memory such as phase change RAM (PRAM), resistive RAM (ReRAM), nano floating gate memory (NFGM), polymer random access memory (PoRAM), magnetic RAM (MRAM), ferroelectric RAM (FRAM), or flash memory.

The input/output device 150 may control user input and output from user interface devices. For example, the input/output device 150 may include an input device such as a keyboard, a mouse, or a touch pad to receive input data defining the integrated circuit. For example, the input/output device 150 may include an output device such as a display or a speaker to display a layout result, a routing result, layout data, and a DRC result.

The storage device 170 may store the programs such as the synthesis module 131, the place and routing module 132, and the DRC module 133, and the program or at least a part thereof may be loaded from the storage device 170 into the memory 130 before the program is executed by the processor 110. The storage device 170 may also store data to be processed by the processor 110 or data processed by the processor 110. For example, the storage device 170 may store data (for example, a standard cell library 171 and netlist data) to be processed by the programs such as the synthesis module 131, the place and routing module 132, and the DRC module 133, and data (for example, DRC result data and layout data) generated by the programs. The standard cell library 171 stored in the storage device 170 may be the standard cell library D10 of FIG. 6.

For example, the storage device 170 may include non-volatile memory such as electrically erasable programmable read-only memory (EEPROM), flash memory, PRAM, RRAM, MRAM, or FRAM, or a storage medium such as memory cards (MMC, eMMC, SD, and MicroSD), a solid state drive (SSD), a hard disk drive (HDD), a magnetic tape, an optical disk, or a magnetic disk. In addition, the storage device 170 may be detachable from the integrated circuit design system 100.

While the present inventive concept has been described with reference to embodiments thereof, it will be understood by those of ordinary skill in the art that various changes in form and details may be made thereto without departing from the spirit and scope of the present inventive concept.

What is claimed is:

1. An integrated circuit including a standard cell having a cell height in a first horizontal direction, wherein the standard cell comprises:
a metal layer including a pattern extending in the first horizontal direction and a plurality of tracks spaced apart from one another in a second horizontal direction; and
at least one via connecting the metal layer to a lower pattern of the metal layer,
wherein the plurality of tracks comprise a plurality of cell tracks and at least one power distribution network (PDN) track, wherein cell patterns are formed on the plurality of cell tracks, and a PDN pattern or a routing pattern is formed on the at least one power distribution network (PDN) track,
wherein a first pattern is spaced apart from a cell boundary of the standard cell by a first length and is formed on a first cell track among the plurality of cell tracks, and
wherein a second pattern is spaced apart from a cell boundary of the standard cell by a second length that is different from the first length and is formed on a second cell track among the plurality of cell tracks.

2. The integrated circuit of claim 1, wherein the first pattern and the second pattern are adjacent to each other in the second horizontal direction, and
wherein the first pattern and the second pattern have a same length as each other.

3. The integrated circuit of claim 1, wherein the first pattern and the second pattern are adjacent to each other in the second horizontal direction, and
wherein a length of the first pattern is less than a length of the second pattern.

4. The integrated circuit of claim 1, wherein a third pattern is spaced apart from a cell boundary of the standard cell by the first length and is formed on a third cell track among the plurality of cell tracks,
wherein a fourth pattern is spaced apart from a cell boundary of the standard cell by the second length and is adjacent to the third pattern in the second horizontal direction, wherein the fourth pattern is formed on a fourth cell track among the plurality of cell tracks, and
wherein the first cell track, the second cell track, the at least one PDN track, the third cell track, and the fourth cell track are sequentially placed on the metal layer in the second horizontal direction.

5. The integrated circuit of claim 1, wherein the standard cell further comprises at least one gate line extending in the first horizontal direction and spaced apart from each other in the second horizontal direction, and
wherein the first cell track is spaced apart from the at least one gate line in the second horizontal direction by a first predetermined distance, and the second cell track is spaced apart from the at least one gate line in the second horizontal direction by a second predetermined distance.

6. The integrated circuit of claim 1, wherein the standard cell further comprises:
at least one gate line extending in the first horizontal direction and spaced apart from each other in the second horizontal direction; and
a nanosheet or a fin-type active region surrounded by the at least one gate line.

7. The integrated circuit of claim 1, wherein the standard cell is continuously placed in a first row with a first height and a second row with a second height.

8. The integrated circuit of claim 7, wherein the first height is equal to the second height.

9. The integrated circuit of claim 7, wherein the first height is different from the second height.

10. An integrated circuit including a standard cell defined by a cell boundary, wherein the standard cell comprises:
a first metal layer and a second metal layer that are sequentially stacked on a substrate, and in each of the first metal layer and the second metal layer, a plurality of patterns are formed; and
at least one via electrically connecting a pattern of the first metal layer to a pattern of the second metal layer,
wherein, on the second metal layer, a pattern extending in a first horizontal direction is formed and a plurality of tracks spaced apart from one another in a second horizontal direction are defined,
wherein the plurality of tracks comprise a plurality of cell tracks and at least one power distribution network (PDN) track, wherein cell patterns are formed on the plurality of cell tracks, and a PDN pattern or a routing pattern is formed on the at least one power distribution network (PDN) track,
wherein a first pattern is spaced apart from a cell boundary of the standard cell by a first length and is formed on a first cell track among the plurality of cell tracks, and
wherein a second pattern is spaced apart from a cell boundary of the standard cell by a second length that is different from the first length and is formed on a second cell track among the plurality of cell tracks.

11. The integrated circuit of claim 10, wherein the first pattern and the second pattern are adjacent to each other in the second horizontal direction, and
wherein the first pattern and the second pattern have a same length as each other.

12. The integrated circuit of claim 10, wherein the first pattern and the second pattern are adjacent to each other in the second horizontal direction, and
wherein a length of the first pattern is less than a length of the second pattern.

13. The integrated circuit of claim 10, wherein, on the first metal layer, a pattern extending in the second horizontal direction is formed and a plurality of tracks spaced apart from one another in the first horizontal direction are provided,
wherein the first length of the first pattern is less than the second length of the second pattern, and
wherein the at least one via connects a pattern, which is formed on a track closest to a cell boundary of the standard cell among the plurality of tracks of the first metal layer, to the first pattern of the first cell track.

14. The integrated circuit of claim 10, wherein the standard cell comprises a plurality of gate lines extending in the first horizontal direction and spaced apart from one another in the second horizontal direction, and
wherein the first cell track is spaced apart from a first gate line among the plurality of gate lines in the second horizontal direction by a first predetermined distance, and the second cell track is spaced apart from the first gate line in the second horizontal direction by a second predetermined distance.

15. The integrated circuit of claim 10, wherein a third pattern is spaced apart from a cell boundary of the standard cell by the first length and is formed on a third cell track among the plurality of cell tracks,
wherein a fourth pattern is spaced apart from a cell boundary of the standard cell by the second length and is adjacent to the third pattern in the second horizontal direction, wherein the fourth pattern is formed on a fourth cell track among the plurality of cell tracks, and
wherein the first cell track, the second cell track, the at least one PDN track, the third cell track, and the fourth cell track are sequentially placed on the second metal layer in the second horizontal direction.

16. A method of manufacturing an integrated circuit, the method comprising:
forming a first standard cell including at least one of a staggered pattern and a long short pattern that are formed on a metal layer; and
placing a second standard cell, which includes at least one of a staggered pattern and a long short pattern that are formed on the metal layer, adjacent to the first standard cell in a first horizontal direction considering tip-to-tip space requirement,
wherein, on the metal layer, a pattern extending in the first horizontal direction is formed and a plurality of tracks spaced apart from one another in a second horizontal direction are provided,
wherein the staggered pattern comprises a first pattern and a second pattern, wherein the first pattern is formed on a first track among the plurality of tracks and is spaced apart from a cell boundary by a first length, and the second pattern is formed on a second track among the plurality of tracks and is spaced apart from a cell boundary by a second length that is different from the first length,
wherein the long short pattern comprises a third pattern and a fourth pattern, wherein the third pattern is formed on the first track among the plurality of tracks and is spaced apart from a cell boundary by a third length, and the fourth pattern is formed on the second track among the plurality of tracks and is spaced apart from a cell boundary by a fourth length that is different from the third length,
wherein the first pattern of the staggered pattern and the second pattern of the staggered pattern have a same length as each other in the first horizontal direction, and
wherein a length of the third pattern of the long short pattern is different from a length of the fourth pattern of the long short pattern in the first horizontal direction.

17. The method of claim 16, wherein each of the first standard cell and the second standard cell comprises the staggered pattern,
wherein the first length, which is with respect to the first pattern that is formed in the first standard cell, is greater than the second length, which is with respect to the second pattern, and
wherein the first length, which is with respect to the first pattern that is formed in the second standard cell, is less than the second length, which is with respect to the second pattern.

18. The method of claim 16, wherein each of the first standard cell and the second standard cell comprises the long short pattern,
wherein the third length, which is with respect to the third pattern that is formed in the first standard cell, is greater than the fourth length, which is with respect to the fourth pattern, and
wherein the third length, which is with respect to the third pattern that is formed in the second standard cell, is less than the fourth length, which is with respect to the fourth pattern.

19. The method of claim 16, further comprising placing a third standard cell including the staggered pattern, which is formed on the metal layer, adjacent to the first standard cell and the second standard cell in the first horizontal direction,
wherein the first standard cell comprises the staggered pattern and the second standard cell comprises the long short pattern.

20. The method of claim 16, further comprising forming a routing pattern electrically connected to an input/output pin of the first standard cell on a track, on which the staggered pattern and the long short pattern are not formed, among the plurality of tracks.
